(19) United States
(12) Patent Application Publication
(10) Pub. No.: US 2002/0142591 A1
(43) Pub. Date: Oct. 3, 2002

(54) Method of synthesizing copper precursors

(76) Inventors: Wei-Wei Zhuang, Vancouver, WA (US); David R. Evans, Beaverton, OR (US); Sheng Teng Hsu, Camas, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 09/820,417

(22) Filed: Mar. 29, 2001

(51) Int. Cl. H01L 21/44

(52) U.S. Cl. 438/687

(57) ABSTRACT

A method is provided for synthesizing relatively pure (hfac)Cu(I)L precursors which can be directly used for CVD copper thin film deposition applications without further purification. The new synthesis method can be applied to the synthesis of copper precursors having ligands such as 1-pentene or 1-hexene. The synthesis method is based on providing a stoichiometric excess of Cu₂O and L as initial reactants, compared to the amount of H(hfac) initially provided. The reaction is carried out at a low temperature, which reduces the occurrence of undesirable side-reactions that would reduce the purity of the copper precursor produced. The reaction has a large synthesis window which enhances the repeatability of the synthesis method so as to meet the requirements of large scale manufacturing production.

### FIELD OF THE INVENTION

The invention relates to a new method of synthesizing (hfac)Cu(I)L (where hfac=1,1,1,5,5,5-hexafluoroacetylacetonate, and L=alkyne or alkene) precursors, which can be used for chemical vapor deposition of pure copper thin films in integrated circuit fabrication.

### BACKGROUND OF THE INVENTION

The demand for progressively small, less expensive, and more powerful electronic products has fueled the need for smaller geometry integrated circuits (ICs) on large substrates. It also creates a demand for a denser packaging of circuits onto IC substrates. The desire for smaller geometry IC circuits requires that the interconnections between components and dielectric layers be as small as possible. Therefore, research continues into reducing the width of via interconnects and connecting lines. The conductivity of the interconnects is reduced as the areas of the interconnecting surfaces is reduced, and the resulting increase in interconnect resistivity has become an obstacle in IC design. Conductors having high resistivity create conduction paths with high impedance and large propagation delays. These problems result in unreliable signal timing, unreliable voltage levels, and lengthy signal delays between components in the IC. Propagation discontinuities also result from intersecting conduction surfaces that are poorly connected, or from the joining of conducts having highly different impedance characteristics.

There is a need for interconnects and vias to have both low resistivity, and the ability to withstand process environments of volatile ingredients. Aluminum and tungsten metals are often used in the production of integrated circuits for making interconnections or vias between electrically active areas. These metals are popular because they are easy to use in a production environment, unlike copper which requires special handling.

However, due to its unique properties, copper (Cu) would appear to be a natural choice to replace aluminum in the effort to reduce the size of lines and vias in an electrical circuit. The conductivity of copper is approximately twice that of aluminum and over three times that of tungsten. As a result, the same current can be carried through a copper line having nearly half the width of an aluminum line.

The electromigration characteristics of copper are also much superior to those of aluminum. Aluminum is approximately ten times more susceptible than copper to degradation and breakage due to electromigration. As a result, a copper line, even one having a much smaller cross-section than an aluminum line, is better able to maintain electrical integrity.

There have been problems associated with the use of copper, however, in IC processing. Copper pollutes many of the materials used in IC processes and, therefore, barriers are typically erected to prevent copper from migrating. Elements of copper migrating into these semiconductor regions dramatically alter the conduction characteristics of associated transistors. Another problem with the use of copper is the relatively high temperature needed to deposit it on, or remove it from, an IC surface. These high temperatures can damage associated IC structures and photoresist masks.

It is a problem to deposit copper onto a substrate, or in a via hole, using the conventional processes for the deposition of aluminum when the geometries of the selected IC features are small. That is, new deposition processes have been developed for use with copper, instead of aluminum, in the lines and interconnects of an IC interlevel dielectric. It is impractical to sputter metal, either aluminum or copper, to fill small diameter vias, since the gap filling capability is poor. To deposit copper, first, a physical vapor deposition (PVD), and then, a chemical vapor deposition (CVD) technique, have been developed in the industry.

With the PVD technique, an IC surface is exposed to a copper vapor, and the copper is caused to condense on the surfaces. The technique is not selective with regard to surfaces. When copper is to be deposited on a metallic surface, adjoining nonconductive surfaces must either be masked or etched clean in a subsequent process step. As mentioned earlier, photoresist masks and some other adjoining IC structure are potentially damaged at the high temperatures at which copper is processed. The CVD technique is an improvement over PVD because it is more selective as to which surfaces copper is deposited on. The CVD technique is selective because it is designed to rely on a chemical reaction between the metallic surface and the copper vapor to cause the deposition of copper on the metallic surface.

In a typical CVD process, copper is combined with a ligand, or organic compound, to help insure that the copper compound becomes volatile, and eventually decomposes, at consistent temperatures. That is, copper becomes an element in a compound that is vaporized into a gas, and later deposited as a solid when the gas decomposes. Selected surfaces of an integrated circuit, such as diffusion barrier material, are exposed to the copper gas, or precursor, in an elevated temperature environment. When the copper gas compound decomposes, copper is left behind on the selected surface. Several copper gas compounds are available for use with the CVD process. It is generally accepted that the configuration of the copper gas compound, at least partially, affects the ability of the copper to be deposited on to the selected surface.

Cu²⁺ (hfac)₂, or copper (II) hexafluoroacetylacetonate, precursors have previously been used to apply CVD copper to IC substrates and surfaces. However, these Cu²⁺ precursors are notable for leaving contaminates in the deposited copper, and for the relatively high temperatures that must be used to decompose the precursor into copper.

Another copper precursor, (hfac)Cu(I)L, or copper (I) hexafluoroacetylacetonate-Ligand (where the Ligand may be one of a variety of ligands), has been prepared. Synthesis methods of this precursor compound have utilized the stoichiometric ratio of the reactants in the reaction. The reaction produces an un-pure (hfac)Cu(I)L product so that further purification is needed. In another prior art method of synthesizing a copper precursor, a reaction is carried out using M(hfac) (where M potassium (K) or sodium (Na)) to react with Cu(I)CI in the presence of a ligand (L). This synthesis method can be used for only some forms of copper precursors, such as when L=tmvs (where tmvs=trimethylvinylsilane), but cannot be used for the synthesis of (hfac)Cu(I)(1-pentene) or (hfac)Cu(I)(1-hexene).

### SUMMARY OF THE INVENTION

The present invention provides a method for synthesizing relatively pure (hfac)Cu(I)L precursors, which can be directly used for CVD copper thin film deposition applications without further purification. The new synthesis method can be applied to the synthesis of copper precursors having ligands such as 1-pentene or 1-hexene. The synthesis method is based on providing a stoichiometric excess of Cu₂O and L as initial reactants, compared to the amount of H(hfac) initially provided. The reaction is carried out at a low temperature, which reduces the occurrence of undesirable side-reactions that would reduce the purity of the copper precursor produced. The reaction has a large synthesis window which enhances the repeatability of the synthesis method so as to meet the requirements of large scale manufacturing production.

Accordingly, an object of the invention is to provide a method of synthesizing a copper precursor that is relatively pure.

Another object of the invention is to provide a method of synthesizing a copper precursor having ligands such as 1-pentene or 1-hexene.

A further object of the invention is to provide a method of synthesizing a copper precursor by providing a stoichiometric excess of Cu₂O and L as initial reactants, compared to the amount of H(hfac) initially provided.

Still another object of the invention is to provide a method of synthesizing a copper precursor that is carried out at a low temperature so as to reduce the occurrence of undesirable side-reactions.

Yet another object of the invention is to provide a method of synthesizing a copper precursor having a large synthesis window which enhances the repeatability of the synthesis method so as to meet the requirements of large scale manufacturing production.

### BRIEF DESCRIPTION OF THE DRAWINGS

FIG. 1 is a flowchart of the method of the present invention.

### DETAILED DESCRIPTION OF THE PREFERRED EMBODIMENTS

The present invention provides a new method of synthesizing a series of copper precursors which can be used as sources for chemical vapor deposition of copper metal thin films in integrated circuit fabrication.

The starting chemicals used for the synthesis are copper monoxide (Cu₂O), 1,1,1,5,5,5-hexafluoroacetylacetone (H(hfac)), L (L=alkyne or alkene) and an organic solvent of methylene chloride (CH₂Cl₂), as shown in equation (1) for the stoichiometric reaction.

Cu₂O+2H(hfac)+2L→2(hfac)Cu(I)L+H₂O (in CH₂Cl₂) (1)

In the inventive synthesis method, extra Cu₂O and stabilizer ligand L are used. The extra amount of Cu₂O added typically is in a range of 1.5 to 3.0 times the stoichiometric ratio, and preferably in a range of 1.9 to 2.1 times the stoichiometric ratio, i.e., approximately double the amount of Cu₂O required for the stoichiometric reaction. The extra amount of stabilizer ligand L added typically is in a range of 3.0 to 8.0 times the stoichiometric ratio, and preferably in a range of 4.0 to 6.0 times the stoichiometric ratio, i.e., approximately four times the amount of ligand required for the stoichiometric reaction. The reaction is carried out in CH₂Cl₂ at 0° C. or less with strong stirring. As shown in equation (1), water is a side-product of the desired synthesis reaction. Applicants have found that this water side-product has some effect on the decomposition of the main product (hfac)Cu(I)L to form Cu metal and Cu(II)(hfac), as shown in equation (2).

2(hfac)Cu(I)L→Cu+Cu(II)(hfac)₂+2L (2)

The mechanism for the water effect is believed to be due to the water's strong coordination to the copper metal center, which results in the decomposition of the product, i.e., the stabilizer ligand L leaving the copper metal center. Further decomposition of the desirable product (hfac)Cu(I)L to Cu and Cu(II)(hfac)₂ is likely due to the poor stabilization property of water. In this decomposition process, water acts as a catalyst. The proposed water effect on the copper precursor decomposition mechanism is described in equations (3) and (4).

(hfac)Cu(I)L+H₂O→(hfac)Cu(I).H₂O+L (3)

2(hfac)Cu(I).H₂O→Cu+Cu(II)(hfac)₂+H₂O (4)

To avoid or reduce this decomposition reaction, Applicants added extra Cu₂O and stabilizer ligand to the initial reactants, and the reaction was carried out at a low temperature. The extra amount of Cu₂O and stabilizer ligand L typically are each in a range of 1.5 to 3.0 and 3.0 to 8.0 times the stoichiometric ratio, respectively, and preferably each in a range of 1.9 to 2.1 and 4.0 to 6.0 times the stoichiometric ratio, respectively. The reaction of the present invention typically is carried out at a temperature of 0° C. or less, whereas prior art synthesis methods typically are carried out at higher temperatures. The extra Cu₂O provides for the possibility of the water to coordinate to the copper metal center of Cu₂O, instead of to the main product (hfac)Cu(I)L. The lower reaction temperature is also believed to resist the water effect on the decomposition of (hfac)Cu(I)L. At the same time, extra stabilizer ligand is introduced for the stabilization of the main product of (hfac)Cu(I)L.

The color of undesirable Cu(II)(hfac)₂ is green and the color of desirable (hfac)Cu(I)L is yellow. Using these color differences, Applicants conducted a series of experiments to verify whether relatively pure (hfac)Cu(I)L copper precursor can be produced using a single reaction step.

The first experiments were carried out by using different extra amounts of Cu₂O in the reaction, while enough extra L was introduced. The reactions were carried out at 0° C. The results indicated that the more Cu₂O used in the reaction, the purer the product that is obtained, until about double the stoichiometric amount of Cu₂O is introduced.

The second series of experiments were carried out using double the stoichiometric amount of Cu₂O, but different amounts of stabilizer ligand of 1-pentene. The results from these experiments also indicate that the more extra 1-pentene used in the reaction, the purer the product that is obtained, until about four times the stoichiometric amount of 1-pentene is introduced.

Further experiments were carried out by changing the reaction temperature. Applicants found that relatively pure (hfac)Cu(I)L cannot be obtained when the reaction is carried out at room temperature, but that the relatively pure compound can be obtained when the reaction temperature is decreased to 0° C. By relatively pure, Applicants mean that the product (hfac)Cu(I)L is produced with a purity or at least 90%, and typically in a range of 95% to 100% purity. The purity of the precursor can be determined by UV spectroscopy because Cu(hfac)2 produces an absorption peak at a wavelength of about 664 nm. Accordingly, Applicants conducted a study using UV to monitor the copper precursor ((1-pentene)Cu(I)hfac)) purity. The reaction proceeds relatively fast at 0° C., and the product is stable even after strong stirring for 20 minutes. For the synthesis detail, two examples have been provided as follows.

### EXAMPLE 1

In the first example, a 3000 mL flask was used for the reaction. The entire process takes place in an Argon atmosphere. Cu₂O (160 gram, 1.118 mol) was weighed and put into the flask, and then 450 mL CH₂CI₂ was added. To this solution, 1-pentene (300 mL) was added. H(hfac) (100 g, 0.48 mol) was added in a dropping funnel which was then attached on the flask. The flask was then put on a Schlenk line. The flask was immersed into an ice bath for 40 minutes and cooled down to 0° C. The H(hfac) was slowly dropped into the solution with strong stirring. The addition of the H(hfac) took about 15 minutes. Strong stirring was maintained during all of the H(hfac) addition. There was no clear color change; the solution was a dilute yellow. The solution was stirred for another 10 minutes, and no color change was observed. The solution was then filtered through a filter paper attached on a plastic tube and transferred into another 2000 mL flask under high Ar pressure. The solvent was then removed under vacuum, during which the color of the solution did not show any change. The yellow liquid filtrate was filtered again through a 0.1 μm filter paper. This produced a dilute yellow product that weighed 139 g (yield: 85%). The density of the compound was measured as 1.47 gram/mL. And finally, extra 1-pentene (95 mL) was added immediately, from which a mixture of (1-pentene)Cu(I)(hfac) and 1-pentene (50:50 volume ratio) was produced. Further purification to remove trace Cu(hfac)2 was conducted by passing the precursor through a column filled with silica gel. This special liquid precursor produced can be used for CVD copper metal thin film deposition.

### EXAMPLE 2

In the second example, a 3000 mL flask was used for the reaction. Cu₂O (160 gram, 1.118 mol) was weighed and put into the flask. To this solution, 1-pentene (700 mL) was added. The H(hfac) (100 g, 0.48 mol) was added in a dropping funnel which was then attached on the flask. The flask was immersed into an ice bath for 40 minutes and cooled down to 0° C. At the same time, Ar gas was introduced into the flask. The H(hfac) was slowly dropped into the solution with strong stirring. The addition of H(hfac) took about 15 minutes. The strong stirring was maintained during all of the H(hfac) addition. There was no clear color change, and the solution was a dilute yellow. The solution was stirred for another 10 minutes, and no color change was observed. Then the solution was filtered through a filter paper attached on a plastic tube and transferred into another 2000 mL flask under high Ar pressure. The solvent was then removed under vacuum, during which the color of the solution did not show any change. The filtrate was filtered again through a 0.1 μm filter paper. This produced a dilute yellow product and weighed 147 g (yield: 90%). The density of the compound was measured as 1.47 gram/mL. And finally, extra 1-pentene (100 mL) was added, from which a mixture of (1-pentene)Cu(I)(hfac) and 1-pentene (50:50 volume ratio) was produced. Further purification to remove trace Cu(hfac)2 was conducted by passing the precursor through a column filled with silica gel. This special liquid precursor can be used for CVD copper metal thin film deposition.

The inventive synthesis method disclosed herein can be applied to the synthesis of a broad range of (hfac)Cu(I)L (L=alkyne or alkene) precursors, such as L=1-hexene, 1-pentene, α-methylstyrene, tmvs, 2-methyl-1-butene, et al. The water amount analysis on the (hfac)Cu(I)(1-pentene) produced indicates that the water content is less than 100 ppm, which strongly supports Applicant's proposed theory of extra Cu₂O absorption to water side-production during the reaction. The inventive reaction has a large synthesis window, i.e., a wide range for the amount of Cu₂O and L which may be introduced (such as the extra ratios set forth above), a wide reaction time range, ease of operation, and ease of control. This large synthesis window enhances the repeatability of the synthesis method so as to meet the requirements of large scale manufacturing production.

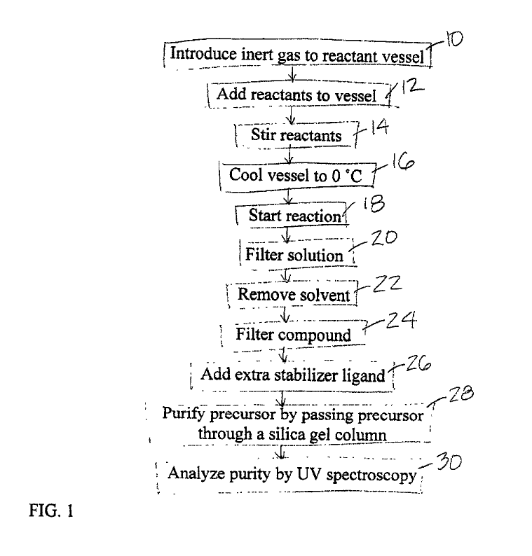

FIG. 1 shows the steps of the disclosed process. Step 10 comprises introducing an inert gas, such as Argon, to the reactant vessel. Step 12 comprises adding to the reactant vessel the following compounds: copper monoxide (Cu₂O), 1,1,1,5,5,5hexafluoroacetylacetone (H(hfac)), a ligand L (such as an alkyne or an alkene, and more particularly, 1-hexene, 1-pentene, α-methylstyrene, tmvs, or 2-methyl-1-butene, et al.) and an organic solvent of methylene chloride (CH₂Cl₂). An extra amount of Cu₂O and stabilizer ligand L typically are added, each being in a range of 1.5 to 3.0 and 3.0 to 8.0 times the stoichiometric ratio, respectively, and preferably each in a range of 1.9 to 2.1 and 4.0 to 6.0 times the stoichiometric ratio, respectively, i.e., approximately double and five times, respectively, the amount of Cu₂O and stabilizer ligand L required for the stoichiometric reaction. Step 14 comprises stirring the reactants. Step 16 comprises bringing the reactants to 0° C. or less, such as in an ice bath. Step 18 comprises starting the reaction in the reaction vessel. Step 20 comprises filtering the solution through a filter paper attached on a plastic tube and transferring it into another 2000 mL flask under high Ar pressure. Step 22 comprises removing the solvent under vacuum. Step 24 comprises filtering the compound again through a 0.1 μm filter paper. Step 26 comprises adding extra 1-pentene (95 to 100 mL) for stabilization over a long time period. Step 28 is an optional step comprising passing the copper precursor through a silica gel column to further purify the copper precursor. Step 30 comprises analyzing the purity and water content of the precursor by UV spectroscopy. The water amount analysis on the (hfac)Cu(I)(1-pentene) produced indicates that the water content is less than 120 ppm, and typically is less than 100 ppm, and that the purity of the copper precursor is at least 90%. The precursor produced typically is stable for at least thirty days.

Thus, a method of synthesizing a copper precursor has been disclosed. Although preferred initial reactants, ligands and reaction conditions of synthesizing the copper precursor have been disclosed, it should be appreciated that further variations and modifications may be made thereto without departing from the scope of the invention as defined in the appended claims.

I claim:

1. A process for producing (hfac)Cu(I)L, comprising the steps of:
mixing copper monoxide (Cu₂O), 1,1,1,5,5,5-hexafluoroacetylacetone (H(hfac)), and a ligand, wherein said copper monoxide is added in an amount of at least 1.5 times the stoichiometric ratio of said H(hfac) added.

2. The process of claim 1 wherein said ligand is added in an amount of at least 3.0 times the stoichiometric ratio of said H(hfac) added.

3. The process of claim 1 wherein an organic solvent of methylene chloride o (CH₂Cl₂) is further added to said copper monoxide (Cu₂O), said 1,1,1,5,5,5-hexafluoroacetylacetone (H(hfac)), and said ligand, and wherein said ligand is chosen from the group consisting of an alkyne and an alkene.

4. The process of claim 1 wherein (hfac)Cu(I)L is produced having a purity of at least 90%.

5. The process of claim 1 wherein said ligand is chosen from the group consisting of 1-hexene, 1-pentene, oc-methylstyrene, tmvs, and 2-methyl-1-butene.

6. The process of claim 1 wherein said process is carried out at a temperature of 0° C. or lower with continuous stirring.

7. The process of claim 1 wherein said process has a large synthesis window.

8. The process of claim 1 wherein said copper monoxide is added in an amount of at least 1.9 times the stoichiometric ratio, and wherein said ligand is added in an amount of at least 4.0 times the stoichiometric ratio

9. A method of synthesizing (hfac)Cu(I)L, comprising the steps of:
mixing copper monoxide (Cu₂O), 1,1,1,5,5,5-hexafluoroacetylacetone (H(hfac)), and a ligand, so as to produce (hfac)Cu(I)L having a purity of at least 90%.

10. The method of claim 9 wherein said copper monoxide is added in an amount of at least 1.9 times the stoichiometric ratio, and wherein said ligand is added in an amount of at least 4.0 times the stoichiometric ratio.

11. The process of claim 9 wherein an organic solvent of methylene chloride (CH₂Cl₂) is further added to said copper monoxide (Cu₂O), said 1,1,1,5,5,5-hexafluoroacetylacetone (H(hfac)), and said ligand, and wherein said ligand is chosen from the group consisting of an alkyne and an alkene.

12. The method of claim 9 wherein said ligand is chosen from the group consisting of 1-hexene, 1-pentene, α-methylstyrene, tmvs, and 2-methyl-1-butene.

13. The method of claim 9 wherein said process is carried out at a temperature of 0° C. or lower.

14. The method of claim 9 wherein said process has a large synthesis window.

15. The method of claim 9 wherein said (hfac)Cu(I)L produced is stable for a time period of at least 30 days.

16. The method of claim 9 wherein said ligand is 1-pentene, and wherein said (hfac)Cu(I)L produced has a water content of 100 ppm or less.

17. A method of fabricating an integrated circuit, comprising the steps of:
producing a copper precursor by the method of mixing copper monoxide (Cu₂O), 1,1,1,5,5,5-hexafluoroacetylacetone (H(hfac)), and a ligand, wherein said copper monoxide is added in an amount of at least 1.5 times the stoichiometric ratio of said H(hfac) added; and
without further purifying said copper precursor produced, conducting chemical vapor deposition of said copper precursor to deposit a thin copper film.

18. The method of claim 17 wherein said ligand is added in an amount of at least 3.0 times the stoichiometric ratio of said H(hfac) added.

19. The method of claim 17 wherein (hfac)Cu(I)L is produced having a purity of at least 95%.

20. The method of claim 17 wherein said ligand is chosen from the group consisting of 1-hexene, 1-pentene, a-methylstyrene, tmvs, and 2-methyl-1-butene.
